(19) United States
(12) Patent Application Publication
(10) Pub. No.: US 2021/0226600 A1
(43) Pub. Date: Jul. 22, 2021

(54) RESONATOR AND FABRICATION METHOD THEREOF

(71) Applicant: Ningbo Semiconductor International Corporation (Shanghai Branch), Shanghai (CN)

(72) Inventor: Guohuang YANG, Ningbo (CN)

(21) Appl. No.: 17/203,041

(22) Filed: Mar. 16, 2021

Related U.S. Application Data
(63) Continuation of application No. PCT/CN2020/098840, filed on Jun. 29, 2020.

(30) Foreign Application Priority Data
Dec. 31, 2019 (CN) 201911415323.6

(51) Int. Cl. H03H 3/02; H01L 41/27; H01L 41/08; H01L 41/047; H01L 41/313; H01L 41/337

(52) U.S. Cl. CPC H03H 3/02; H01L 41/27; H01L 41/337; H01L 41/0472; H01L 41/313; H01L 41/0815

(57) ABSTRACT

The present disclosure provides a resonator and its fabrication method. The method includes providing a first substrate; forming a piezoelectric stacked layer-structure on the first substrate; forming a sacrificial layer covering the piezoelectric stacked layer-structure on a working region; providing a second substrate; forming an adhesive layer on the second substrate; attaching a second back surface of the adhesive layer to the sacrificial layer and the piezoelectric stacked layer-structure exposed by the sacrificial layer, where the adhesive layer covers sidewalls of the sacrificial layer and is filled between the second substrate and the piezoelectric stacked layer-structure; removing the first substrate to expose a first front surface of the piezoelectric stacked layer-structure; forming release holes passing through the piezoelectric stacked layer-structure, or forming release holes passing through the second substrate; and removing the sacrificial layer through the release holes to form a cavity.

### CROSS-REFERENCE TO RELATED APPLICATIONS

This application is a continuation application of PCT Patent Application No. PCT/CN2020/098840, filed on Jun. 29, 2020, which claims priority to Chinese patent application No. 201911415323.6, filed on Dec. 31, 2019, the entirety of all of which is incorporated herein by reference.

### FIELD OF THE DISCLOSURE

The present disclosure generally relates to the field of semiconductors, and more particularly, relates to a resonator and its fabrication method.

### BACKGROUND

With the development of mobile communication technology, the mobile data transmission volume has increased rapidly. Therefore, under the premise that frequency resources are limited and as few mobile communication devices as possible should be used, increasing the transmission power of wireless power transmission devices, such as wireless base stations, micro base stations or repeaters, must be considered; meanwhile, the filter power requirement in the front-end circuits of mobile communication devices may also be increasing.

Currently, high-power filters in devices, such as wireless base stations, are mainly cavity filters with power reaching hundreds of watts. Moreover, dielectric filters, which have the average power reaching more than 5 watts, may also be used in certain devices. Such two types of filters may be difficult to be integrated into the RF front-end chips due to their relatively large sizes.

Film bulk acoustic resonators (FBAR) based on semiconductor micromanufacturing technology may effectively overcome the defects of the above-mentioned two types of filters. FBAR has high operation frequency, high withstand power, high quality factor (Q factor), and small size, which is beneficial for integration, and also has the advantages including desirable compatibility with silicon wafer process, reliability, and the like.

### BRIEF SUMMARY OF THE DISCLOSURE

One aspect of the present disclosure provides a method for fabricating a resonator, including providing a first substrate; forming a piezoelectric stacked layer-structure on the first substrate, where the piezoelectric stacked layer-structure includes a working region, and a surface of the piezoelectric stacked layer-structure in contact with the first substrate is a first front surface; forming a sacrificial layer covering the piezoelectric stacked layer-structure on the working region; providing a second substrate; forming an adhesive layer on the second substrate, where a surface of the adhesive layer in contact with the second substrate is a second front surface, and a surface of the adhesive layer opposite to the second front surface is a second back surface; attaching the second back surface of the adhesive layer to the sacrificial layer and the piezoelectric stacked layer-structure exposed by the sacrificial layer, such that the adhesive layer covers sidewalls of the sacrificial layer and is filled between the second substrate and the piezoelectric stacked layer-structure; after attaching the second back surface of the adhesive layer to the sacrificial layer and the piezoelectric stacked layer-structure exposed by the sacrificial layer, removing the first substrate to expose the first front surface of the piezoelectric stacked layer-structure; forming release holes passing through the piezoelectric stacked layer-structure, or forming release holes passing through the second substrate, where the release holes expose the sacrificial layer; and removing the sacrificial layer through the release holes to form a cavity.

Another aspect of the present disclosure provides a resonator, including a substrate; an adhesive layer on the substrate; a piezoelectric stacked layer-structure on the adhesive layer, where the piezoelectric stacked layer-structure includes a working region; the piezoelectric stacked layer-structure at the working region and the adhesive layer encloses a cavity; and a sidewall of the cavity exposes the adhesive layer; and release holes passing through the piezoelectric stacked layer-structure, or passing through the substrate, where the release holes are connected to the cavity.

Other aspects of the present disclosure can be understood by those skilled in the art in light of the description, the claims, and the drawings of the present disclosure.

### BRIEF DESCRIPTION OF THE DRAWINGS

In order to clearly explain the technical solutions in various embodiments of the present disclosure or the existing technology, the drawings that need to be used in the description of the embodiments or the existing technology are illustrated hereinafter. Obviously, the drawings in the following description are merely some embodiments of the present disclosure. For those skilled in the art, other drawings can be obtained based on such drawings without creative work.

FIGS. 1-13 illustrate structural schematics corresponding to certain stages of a resonator fabrication method according to various embodiments of the present disclosure.

### DETAILED DESCRIPTION

It can be known from the background technology that the film bulk acoustic resonator (FBAR) has been widely used. However, the performance of the currently formed resonator may not be desirable.

For example, the current fabrication process of the film bulk acoustic resonator is described as the following. A trench is usually formed in a substrate and a sacrificial layer is formed in the trench, and then a piezoelectric stacked layer-structure is sequentially formed on the sacrificial layer. In order to release the sacrificial layer in the trench, it is usually necessary to form a release hole passing through the piezoelectric stacked layer-structure. Using the release hole, a sacrificial material layer in the trench is removed to form a cavity finally.

The steps for forming the sacrificial layer usually includes forming the sacrificial material layer in the trench and on the substrate; and removing the sacrificial material layer higher than the substrate by polishing, where the remaining sacrificial material layer in the trench is used as the sacrificial layer.

However, the materials of the sacrificial layer and the substrate are different, so that the materials of the sacrificial layer and the substrate have different hardness and mechanical strength. For example, the material of the sacrificial layer is soft and easy to be removed, which results in a relatively fast polishing rate at the top of the sacrificial material layer when the sacrificial material layer higher than the substrate is removed by polishing. The height consistency between the top of the sacrificial layer and the surface of the substrate is poor. For example, recessions are easily formed at the top of the sacrificial layer, and steps are easily formed between the top of the sacrificial layer and the top surface of the substrate. It may result in poor flatness and height consistency between the sacrificial layer and the substrate surface, and further easily affect the film growth quality of the piezoelectric stacked layer-structure. For example, the lattice orientation uniformity, thickness uniformity, and film continuity of each film layer in the piezoelectric stacked layer-structure may be affected, thereby further reducing the performance of the resonator easily.

In order to solve the above-mentioned technical problem, the present disclosure provides a method for fabricating a resonator. The method may include providing a first substrate; forming a piezoelectric stacked layer-structure on the first substrate, where the piezoelectric stacked layer-structure may include a working region, and the surface of the piezoelectric stacked layer-structure in contact with the first substrate is a first front surface; forming a sacrificial layer covering the piezoelectric stacked layer-structure on the working region; providing a second substrate; forming an adhesive layer on the second substrate, where the surface of the adhesive layer in contact with the second substrate is a second front surface, and the surface of the adhesive layer opposite to the second front surface is a second back surface; attaching the second back surface of the adhesive layer to the sacrificial layer and the piezoelectric stacked layer-structure exposed by the sacrificial layer, such that the adhesive layer covers the sidewalls of the sacrificial layer and is filled between the second substrate and the piezoelectric stacked layer-structure; after implementing the attaching step, removing the first substrate to expose the first front surface of the piezoelectric stacked layer-structure; forming release holes passing through the piezoelectric stacked layer-structure, or forming release holes passing through the second substrate, where the release holes expose the sacrificial layer; and removing the sacrificial layer through the release holes to form a cavity.

In the method for fabricating the resonator provided in various embodiments of the present disclosure, after forming the piezoelectric stacked layer-structure on the first substrate, the sacrificial layer covering the piezoelectric stacked layer-structure may be formed on the working region; then, the second back surface of the adhesive layer may be attached to the sacrificial layer and the piezoelectric stacked layer-structure exposed by the sacrificial layer, such that the adhesive layer may cover the sidewalls of the sacrificial layer and be filled between the second substrate and the piezoelectric stacked layer-structure to implement the attaching; then, the first substrate may be removed, the release holes may be formed, and the sacrificial layer may be removed through the release holes to form the cavity. In various embodiments of the present disclosure, when the piezoelectric stacked layer-structure is formed, no sacrificial layer may be formed on the surface of the first substrate, and the surface of the first substrate may have desirable flatness, which is beneficial for providing a desirable interface for forming the piezoelectric stacked layer-structure on the first substrate, thereby improving the formation quality of each film layer in the piezoelectric stacked layer-structure. For example, it is beneficial for improving the thickness uniformity, lattice orientation uniformity, film continuity and the like of each film layer in the piezoelectric stacked layer-structure, and it is more beneficial for improving the resonator performance. Moreover, the present disclosure may also utilize the plasticity of the adhesive layer to attach the second substrate to the first substrate formed with a protrusion structure, and accordingly realize the sealing of the sacrificial layer, such that it is beneficial for improving the convenience and operability of forming the cavity and saving cost.

In order to clearly illustrate the above-mentioned objectives, features and advantages of the present disclosure, various embodiments of the present disclosure are described in detail with reference to the accompanying drawings hereinafter.

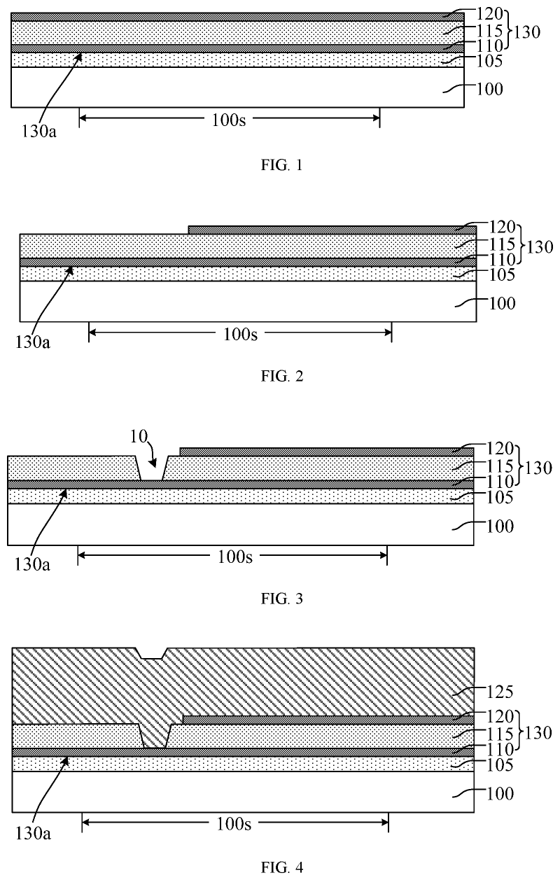

FIGS. 1-13 illustrate structural schematics corresponding to certain stages of a resonator fabrication method according to various embodiments of the present disclosure.

Referring to FIG. 1, a first substrate 100 may be provided.

The first substrate 100 may provide a process platform for subsequent processes.

In one embodiment, the first substrate 100 may be any suitable substrate known to those skilled in the art. For example, the third substrate 300 may be made of a material including at least one of the materials mentioned below: silicon (Si), germanium (Ge), silicon germanium (SiGe), silicon carbon (SiC), silicon germanium (SiGeC), indium arsenide (InAs) , Gallium arsenide (GaAs), indium phosphide (InP) or other III/V compound semiconductors; a multilayer-structure composed of such semiconductors; silicon-on-insulator (SOI), silicon-on-insulator (SSOI), silicon-germanium-on-insulator (S-SiGeOI), silicon germanium-on-insulator (SiGeOI), and germanium-on-insulator (GeOI); and a double side polished wafer (DSP), a ceramic substrate such as alumina, a quartz or glass substrate, and/or the combination thereof.

The fabrication method may further include a subsequent step of forming the piezoelectric stacked layer-structure on the first substrate 100. In one embodiment, before forming the piezoelectric stacked layer-structure on the first substrate 100, the method for forming the resonator may further include forming a buffer layer 105 on the first substrate 100.

The buffer layer 105 may be used to improve the interface quality on the surface of the first substrate 100 and serve as a transition layer between the subsequent piezoelectric stacked layer-structure and the first substrate 100, thereby improving the growth consistency of the subsequent piezoelectric stacked layer-structure and the adhesion between the first substrate 100 and the piezoelectric stacked layer-structure. Moreover, after subsequently forming an adhesive layer on the second substrate and attaching the adhesive layer to the sacrificial layer and the piezoelectric stacked layer-structure exposed by the sacrificial layer, the method of forming the resonator may further include removing the first substrate 100. The buffer layer 105 may also be used as a stop layer in the step of removing the first substrate 100 to reduce the difficulty of removing the first substrate 100, which may be beneficial for preventing the subsequent removal of the first substrate 100 from affecting the piezoelectric stacked layer-structure.

The buffer layer 105 may be made of a material including one or more of silicon oxide, silicon nitride, and silicon oxynitride. In one embodiment, the material of the buffer layer 105 may be silicon oxide.

In one embodiment, the buffer layer 105 may be formed by a deposition process. For example, the deposition process may be a chemical vapor deposition process, an atomic layer deposition process, and the like.

Referring to FIG. 1, a piezoelectric stacked layer-structure 130 may be formed on the first substrate 100. The piezoelectric stacked layer-structure 130 may include a working region 100s, and the surface of the piezoelectric stacked layer-structure 130 facing toward the first substrate 100 may be a first front surface 130a.

The piezoelectric stacked layer-structure 130 may be used to realize the mutual conversion between electrical signals and acoustic signals, such that the resonator may perform filtering processing on the signals.

In one embodiment, the piezoelectric stacked layer-structure 130 may include the working region 100s. The working region 100s may include a working region of the resonator for implementing the filtering function; and a cavity may be formed in the working region 100s subsequently.

In one embodiment, the piezoelectric stacked layer-structure 130 may include a first electrode layer 110, a piezoelectric layer 115 on the first electrode layer 110, and a second electrode layer 120 on the piezoelectric layer 115. The surface of the first electrode layer 110 in contact with the first substrate 100 may be the first front surface 130a.

The fabrication method may further include a subsequent step of forming the sacrificial layer covering the piezoelectric stacked layer-structure 130 on the working region 100s. In one embodiment, the piezoelectric stacked layer-structure 130 may be first formed on the first substrate 100; and in the process of forming the piezoelectric stacked layer-structure 130, no sacrificial layer may be formed on the first substrate 100, and the surface of the first substrate 100 may have desirable flatness, which is beneficial for providing a desirable interface for forming the piezoelectric stacked layer-structure 130, thereby improving the formation quality of the first electrode layer 110, the piezoelectric layer 115 and the second electrode layer 120 in the piezoelectric stacked layer-structure. For example, it is beneficial for improving the thickness uniformity, lattice orientation uniformity, film continuity and the like of each film layer in the piezoelectric stacked layer-structure 130, and it is more beneficial for improving the resonator performance.

In one embodiment, the first electrode layer 110 may be used to form a bottom electrode.

The first electrode layer 110 may be made of a material including a conductive material or a semiconductor material. The conductive material may be a metal material with conductive properties including, for example, Al, Cu, Pt, Au, Ir, Os, Re, Pd, Rh, Ru, Mo, W or a combination thereof; and the semiconductor material may include, for example, Si, Ge, SiGe, SiC, SiGeC, or a combination thereof.

In one embodiment, the first electrode layer 110 may be formed by a physical vapor deposition process.

The piezoelectric layer 115 may be made of a piezoelectric material having piezoelectric effect. In other words, the piezoelectric material may be a crystalline material that generates voltage between two ends when it's subjected to pressure; and the piezoelectric effect of the piezoelectric material may be used to realize the mutual conversion between mechanical vibration (acoustic wave) and alternating current, thereby realizing the conversion of acoustic energy and electric energy.

The piezoelectric layer 115 may be made of a piezoelectric material having a wurtzite crystal structure including ZnO, AlN, GaN, aluminum zirconate titanate, lead titanate, or a combination thereof. In one embodiment, the material of the piezoelectric layer 115 may be AlN.

In one embodiment, the piezoelectric layer 115 may be formed by a deposition process such as a chemical vapor deposition process, a physical vapor deposition process, an atomic layer deposition process, or a combination thereof.

In one embodiment, the second electrode layer 120 may be used to form a top electrode.

The second electrode layer 120 may be made of a material including a conductive material or a semiconductor material. The conductive material may be a metal material with conductive properties including, for example, Al, Cu, Pt, Au, Ir, Os, Re, Pd, Rh, Ru, Mo, W, or a combination thereof. The semiconductor material may include, for example, Si, Ge, SiGe, SiC, SiGeC, or a combination thereof.

The fabrication method may further include a subsequent step of forming the sacrificial layer on the piezoelectric stacked layer-structure 130 at the working region 100s.

Referring to FIGS. 2-3, in one embodiment, after forming the piezoelectric stacked layer-structure 130 on the first substrate 100 and before forming the sacrificial layer, the method for forming the resonator may further include forming a first trench 10 in the piezoelectric stacked layer-structure 130 at the working region 100s.

The first trench 10 may be used to laterally reflect the acoustic wave, thereby being beneficial for increasing the residence time of the acoustic wave in the cavity and further reducing energy dissipation, and correspondingly, being beneficial for improving the acoustic-electric conversion performance of the resonator. In other embodiments, the first trench may also be used to define the edge of the active region of the resonator, that is, the edge of the effective resonance region selected by the resonator; and the first trench and the second trench formed subsequently together may define the effective resonance region.

In one embodiment, when forming the first trench 10, the bottom of the first trench 10 may expose the first electrode layer 110.

It should be noted that, referring to FIG. 2, in one embodiment, after forming the piezoelectric stacked layer-structure 130 and before forming the first trench 10, the method for forming the resonator may further include patterning the second electrode layer 120 to expose a portion of the piezoelectric layer 115 at the working region 100s.

The upper electrode may be formed by performing patterning treatment on the second electrode layer 120. In one embodiment, the edge of the effective resonance region may also be defined by the pattern of the upper electrode.

In one embodiment, a dry etching process may be used to pattern the second electrode layer 120.

Therefore, in one embodiment, when forming the first trench 10, the first trench 10 may pass through the piezoelectric layer 115, and the bottom of the first trench 10 may expose the first electrode layer 110.

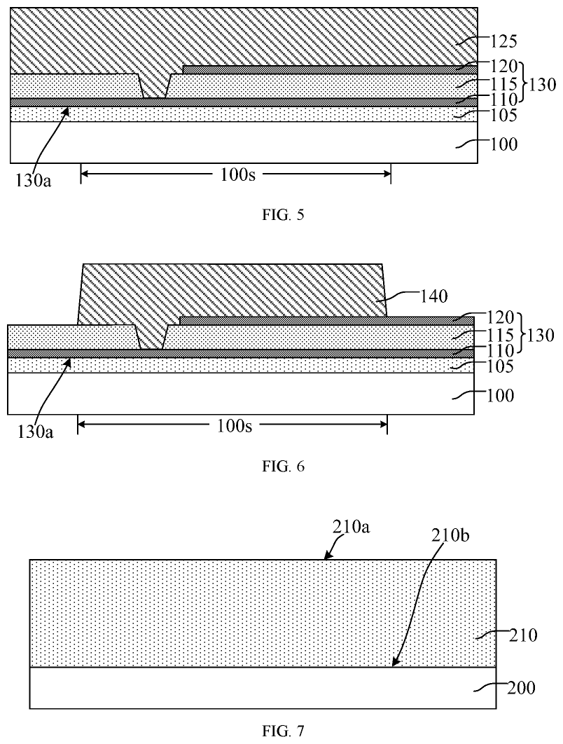

Referring to FIGS. 4-6, a sacrificial layer 140 covering the piezoelectric stacked layer-structure 130 may be formed on the working region 100s.

The sacrificial layer 140 may be used to occupy a space for the subsequent formation of the cavity, that is, the sacrificial layer 140 may be subsequently removed to form the cavity at the position of the sacrificial layer 140.

Therefore, the sacrificial layer 140 may be a material that is easy to be removed, and the subsequent process of removing the sacrificial layer 140 may have a relatively small influence on the piezoelectric stacked layer-structure 130. Furthermore, the material of the sacrificial layer 140 may ensure that the sacrificial layer 140 has desirable coverage, thereby completely covering the piezoelectric stacked layer-structure 130 of the working region 100s.

The sacrificial layer 140 may be made of a material including phosphorus-doped silicon oxide glass (PSG), Li₂TiO₃ (LTO), boron and phosphorus-doped silicon oxide glass (BPSG), Ge, photoresist, polysilicon, amorphous carbon, or a combination thereof. In one embodiment, the material of the sacrificial layer 140 may be PSG.

In one embodiment, when forming the sacrificial layer 140, the sacrificial layer 140 may also be filled in the first trench 10.

In one embodiment, forming the sacrificial layer 140 may include:

as shown in FIG. 4, forming a sacrificial material layer 125 on the piezoelectric stacked layer-structure 130.

The sacrificial material layer 125 may be used to form the sacrificial layer.

In one embodiment, the sacrificial material layer 125 may be formed by a chemical vapor deposition (CVD) process.

In one embodiment, the sacrificial material layer 125 may also be filled in the first trench 10.

As shown in FIG. 5, a planarization treatment may be performed on the sacrificial material layer 125.

The planarization on the top surface of the sacrificial material layer 125 may be realized by performing the planarization treatment on the sacrificial material layer 125, thereby improving the flatness of the subsequent sacrificial layer surface.

In one embodiment, a chemical mechanical polishing (CMP) process may be used to planarize the sacrificial material layer 125.

As shown in FIG. 6, after the sacrificial material layer 125 is planarized, the sacrificial material layer 125 may be patterned, and the sacrificial material layer at the working region 100s may be retained as the sacrificial layer 140.

In one embodiment, a dry etching process, such as an anisotropic dry etching process, may be used to pattern the sacrificial material layer 125.

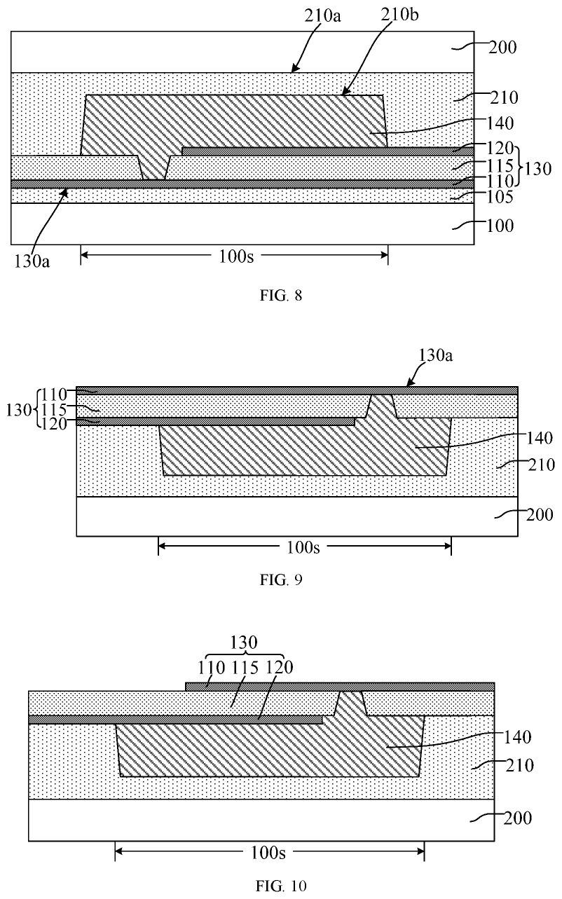

Referring to FIG. 7, a second substrate 200 may be provided.

The fabrication method may further include subsequent steps: forming an adhesive layer on the second substrate 200 and attaching the adhesive layer to the sacrificial layer 140 and the piezoelectric stacked layer-structure 130 exposed by the sacrificial layer 140.

The second substrate 200 may be used to provide a process platform for the subsequent formation of the adhesive layer and the attaching of the adhesive layer with the sacrificial layer 140.

In one embodiment, the second substrate 200 may be any suitable substrate known to those skilled in the art. For example, the second substrate 200 may be made of a material including at least one of the materials mentioned below: silicon (Si), germanium (Ge), silicon germanium (SiGe), silicon carbon (SiC), silicon germanium (SiGeC), indium arsenide (InAs), Gallium arsenide (GaAs), indium phosphide (InP) or other III/V compound semiconductors; a multilayer-structure composed of such semiconductors; silicon-on-insulator (SOI), silicon-on-insulator (SSOI), silicon-germanium-on-insulator (S-SiGeOI), silicon germanium-on-insulator (SiGeOI), and germanium-on-insulator (GeOI); and a double side polished wafer (DSP), a ceramic substrate such as alumina, a quartz or glass substrate, and/or the combination thereof.

Referring to FIG. 7, an adhesive layer 210 may be formed on the second substrate 200. The surface of the adhesive layer 210 in contact with the second substrate 200 is a second front surface 210a, and the surface of the adhesive layer 210 opposite to the second front surface 210a is a second back surface 210b.

The fabrication method may further include a subsequent step: attaching the second back surface 210b of the adhesive layer 210 to the sacrificial layer 140 and the piezoelectric stacked layer-structure 130 exposed by the sacrificial layer 140. In such way, the adhesive layer 210 may cover the sidewalls of the sacrificial layer 140 and be filled between the second substrate 200 and the piezoelectric stacked layer-structure 130. Therefore, the sacrificial layer 140 may be sealed by the adhesive layer 210; and after the sacrificial layer 140 is subsequently removed, the cavity may be formed at the position of the sacrificial layer 140.

In one embodiment, the adhesive layer 210 may be a deformable material. For example, the adhesive layer 210 may be an organic material with strong adhesion, such that the attaching may be achieved through the adhesive layer 210.

For example, the adhesive layer 210 may be a thermal-deformable material, and the thermal-deformable adhesive layer 210 may become soft after being heated, such that the adhesive layer 210 has strong plasticity. When the second back surface 210b of the adhesive layer 210 is subsequently attached to the sacrificial layer 140 and the piezoelectric stacked layer-structure 130 exposed by the sacrificial layer 140, the adhesive layer 210 may be squeezed/deformed and filled between the second substrate 200 and the piezoelectric stacked layer-structure 130. Therefore, the second substrate 200 may be attached to the first substrate 100 formed with the protrusion structure through the adhesive layer 210, thereby sealing the sacrificial layer 140 accordingly.

In one embodiment, the material of the adhesive layer 210 may be a dry film.

The dry film may be a viscous photoresist film used in semiconductor chip packaging or printed circuit board manufacturing. In one embodiment, the dry film photoresist may be manufactured by coating a solvent-free photoresist on a polyester base which is covered with a polyethylene film. When applying the dry film photoresist, the polyethylene film may be peeled off, the solvent-free photoresist may be pressed on a substrate, and a pattern may be formed in the dry film photoresist after exposure and development.

In other embodiments, the material of the adhesive layer may also be other organic material with strong adhesion, such as a die attach film (DAF).

In one embodiment, the adhesive layer 210 may be formed by a process including a spin coating process.

It should be noted that the fabrication method may further include a subsequent step: attaching the second back surface 210b of the adhesive layer 210 to the sacrificial layer 140 and the piezoelectric stacked layer-structure 130 exposed by the sacrificial layer 140. The adhesive layer 210 needs to be able to seal the sacrificial layer 140. Therefore, when forming the adhesive layer 210, the thickness of the adhesive layer 210 needs to be determined according to the thickness of the sacrificial layer 140. In one embodiment, the thickness of the adhesive layer 210 needs to be greater than the thickness of the subsequent sacrificial layer 140.

In one embodiment, when forming the adhesive layer 210, the thickness of the adhesive layer 210 may be about 0.5 micrometer to about 40 micrometers, for example, about 15 micrometers or 20 micrometers.

Referring to FIG. 8, the second back surface 210b of the adhesive layer 210 may be attached to the sacrificial layer 140 and the piezoelectric stacked layer-structure 130 exposed by the sacrificial layer 140, such that the adhesive layer 210 may cover the sidewalls of the sacrificial layer 140 and be filled between the second substrate 200 and the piezoelectric stacked layer-structure 130.

For example, the adhesive layer 210 may cover the top and sidewalls of the sacrificial layer 140, and the piezoelectric stacked layer-structure 130 exposed by the sacrificial layer 140 to achieve the attaching step, such that the adhesive layer 210 may seal the sacrificial layer 140.

Therefore, the cavity may be formed after the first substrate 100 is subsequently removed, release holes exposing the sacrificial layer 140 may be formed, and the sacrificial layer 140 may be removed through the release holes.

In one embodiment, using the deformability and plasticity of the adhesive layer 210, the second substrate 200 may be attached to the first substrate 100 formed with the protrusion structure. In other words, the second substrate 200 may be attached to the first substrate 100 where the sacrificial layer 140 is formed, thereby achieving the sealing of the sacrificial layer 140 accordingly, which is beneficial for improving the convenience and operability of the cavity formation and saving costs.

In one embodiment, the attaching step may be realized using a bonding process. The attachment may be achieved by bonding, such that the process of sealing the sacrificial layer 140 may be compatible with the existing bonding process, which is beneficial for improving process integration and process compatibility.

For example, in one embodiment, the adhesive layer 210 may be made of a relatively soft and thermal deformable material. During the bonding process, the second back surface 210b of the adhesive layer 210 may be pressed onto the sacrificial layer 140, and the adhesive layer 210 may be heated up; and the adhesive layer 210 may be soft after being heated. In such way, the adhesive layer 210 may be filled into the gap formed between the sidewalls of the sacrificial layer 140 and the piezoelectric stacked layer-structure 130, thereby sealing the top and sidewalls of the sacrificial layer 140.

In one embodiment, the adhesive layer 210 may be ensured to be sufficiently soft, such that the adhesive layer 210 may attach the second substrate 200 to the first substrate 100 with the formed protrusion structure and seal the top and sidewalls of the sacrificial layer 140; meanwhile, it is also necessary to prevent the excessive temperature from causing damage to the piezoelectric stacked layer-structure 130 or other film structure, or from affecting the adhesion of the adhesive layer 210. In one embodiment, the temperature of the bonding process may be about 50° C. to about 300° C.

It should be noted that in order to ensure that the adhesive layer 210 can seal the top and side walls of the sacrificial layer 140, in one embodiment, the thickness of the adhesive layer 210 may be relatively large when forming the adhesive layer 210. The thickness of the adhesive layer 210 may be greater than the thickness of the sacrificial layer 140 which needs to be formed.

Therefore, when attaching the adhesive layer 210 to the sacrificial layer 140 and the piezoelectric stacked layer-structure 130 exposed by the sacrificial layer 140, a portion of the adhesive layer 210 may be retained between the top surface of the sacrificial layer 140 and the second substrate 200, which may be beneficial for prevent the problem that a portion of the adhesive layer 210 and the piezoelectric stacked layer-structure 130 are not completely attached, and correspondingly, may be beneficial for prevent the problem that a gap is between the adhesive layer 210 and the piezoelectric stacked layer-structure 130. Therefore, it may ensure that the adhesive layer 210 seals the top and side walls of the sacrificial layer 140, which is beneficial for improving process stability and reducing process risks. Moreover, by retaining the portion of the adhesive layer 210 between the top surface of the sacrificial layer 140 and the second substrate 200, it may be beneficial for reducing the attaching difficulty.

For example, in one embodiment, the thickness of the adhesive layer 210 between the top surface of the sacrificial layer 140 and the second substrate 200 may be about 0.5 micrometer to about 35 micrometers, for example, 15 micrometers.

In other embodiments, according to actual processes, when realizing the attaching process, a portion of the adhesive layer may not be retained between the top surface of the sacrificial layer and the second substrate, that is, the top surface of the sacrificial layer may be in contact with the second substrate directly. Correspondingly, the adhesive layer may be filled between the second substrate and the piezoelectric stacked layer-structure, thereby sealing the top surface and the sidewalls of the sacrificial layer by the second substrate and the adhesive layer.

Referring to FIG. 9, after the attaching is achieved, the first substrate 100 may be removed to expose the first front surface 130a of the piezoelectric stacked layer-structure 130.

The first substrate 100 may be removed to expose the first front surface 130a of the piezoelectric stacked layer-structure 130, which is prepared for subsequent processes.

In one embodiment, the first front surface 130a of the piezoelectric stacked layer-structure 130 may be exposed, which is prepared for the subsequent formation of release holes passing through the piezoelectric stacked layer-structure 130.

In one embodiment, removing the first substrate 100 may include polishing the first substrate 100 to remove a portion of the first substrate 100; and after the first substrate 100 is polished, removing the remaining portion of the first substrate 100 using a wet etching process.

By performing the polishing treatment on the first substrate 100, the thickness reduction of the first substrate 100 may be realized, thereby reducing the difficulty of a subsequent wet etching process.

In one embodiment, a chemical mechanical polishing process may be used to polish the first substrate 100.

In one embodiment, the etching solution of the wet etching process may include tetramethylammonium hydroxide (TMAH), and the like.

It should be noted that, in one embodiment, when removing the first substrate 100, the buffer layer 105 may be used as a stop layer to remove the first substrate 100, which is beneficial for reducing the difficulty of removing the first substrate 100 and preventing the removing process of the first substrate 100 from causing damage to the piezoelectric stacked layer-structure 130.

In one embodiment, after the first substrate 100 is removed, the method for forming the resonator may further include removing the buffer layer 105.

For example, a wet etching process may be used to remove the buffer layer 105. In one embodiment, the wet etching process may be performed using a hydrofluoric acid solution.

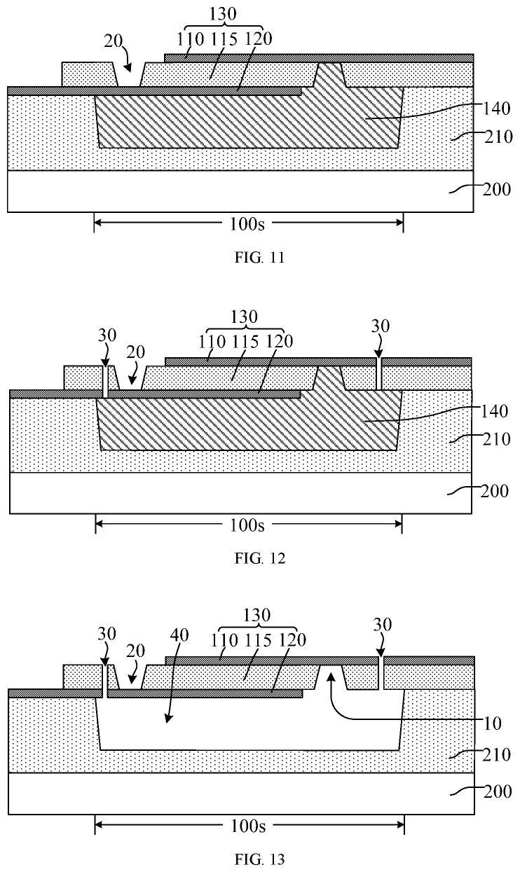

It should be noted that, in one embodiment, referring to FIG. 10, after the first substrate 100 is removed, the method for forming the resonator may further include patterning the first electrode layer 110 to expose a portion of the piezoelectric layer 115 at the working region 100s.

The first electrode layer 110 may be patterned to form a bottom electrode.

In one embodiment, a dry etching process may be used to pattern the first electrode layer 110.

Referring to FIG. 11, in one embodiment, after the first substrate 100 is removed to expose the first front surface 130a of the piezoelectric stacked layer-structure 130, the method for forming the resonator may further include forming a second trench 20 in the piezoelectric stacked layer-structure 130 at the working region 100s.

The second trench 20 may be used to laterally reflect the acoustic wave, thereby being beneficial for increasing the residence time of the acoustic wave in the cavity and further reducing energy dissipation, and correspondingly, being beneficial for improving the acoustic-electric conversion performance of the resonator. In other embodiments, the second trench may also be used to define the edge of the active region of the resonator, that is, the edge of the effective resonance region selected by the resonator; and the first trench and the second trench formed subsequently together may define the effective resonance region.

In one embodiment, the first substrate 100 may be removed to expose the first front surface 130a of the piezoelectric stacked layer-structure 130, such that it is easy to form the second trench 20 in the piezoelectric stacked layer-structure 130, thereby further improving the performance of the resonator.

In one embodiment, when forming the second trench 20, the bottom of the second trench 20 may expose the second electrode layer 120.

In one embodiment, when forming the second trench 20, the piezoelectric layer 115 may be further patterned to define the working region.

Referring to FIG. 12, release holes 30 passing through the piezoelectric stacked layer-structure 130 may be formed, or release holes 30 passing through the second substrate 200 may be formed, where the release holes 30 may expose the sacrificial layer 140.

The release holes 30 may expose the sacrificial layer 140, such that the sacrificial layer 140 may be removed through the release holes 30 subsequently.

In one embodiment, the quantity of the release holes 30 may be more than one, thereby improving the subsequent removal efficiency of the sacrificial layer 140 through the release holes 30.

As an example, the release holes 30 may pass through the piezoelectric stacked layer-structure 130 in one embodiment.

In other embodiments, the release holes may also pass through the second substrate. Correspondingly, when the adhesive layer is retained between the top of the sacrificial layer and the second substrate, the release holes may correspondingly pass through the second substrate and the adhesive layer to expose the sacrificial layer. The release holes may pass through the second substrate, which is beneficial for preventing damage to the piezoelectric stacked layer-structure.

In one embodiment, a dry etching process may be used to etch the piezoelectric stacked layer-structure 130 to form the release holes 30.

Referring to FIG. 13, the sacrificial layer 140 may be removed through the release holes 30 to form a cavity 40.

By setting the cavity 40, the piezoelectric stacked layer-structure 130 may be in contact with the air, such that the acoustic wave may be reflected at the interface between the cavity 40 and the piezoelectric stacked layer-structure 130 to generate normal vibrations when the resonator is operating, thereby making the resonator work normally. Moreover, the piezoelectric stacked layer-structure 130 may be in contact with air, which can effectively reflect the leakage acoustic wave of the resonator from the interface between the air and the piezoelectric stacked layer-structure 130 back to the surface of the substrate, thereby improving the conversion efficiency of electrical and mechanical energy, that is, improving the quality factor (Q factor).

In one embodiment, a wet etching process may be used to remove the sacrificial layer 140. The etching solution of the wet etching process may include a buffered oxide etch (BOE) solution or an HF solution, where the BOE solution may be made by mixing hydrofluoric acid and water or mixing ammonium fluoride and water.

In one embodiment, after forming the cavity 40, the opening of the first trench 10 may be connected to the cavity 40, such that the first trench 10 may laterally reflect the acoustic wave, thereby further reducing energy dissipation and improving the acoustic-electric conversion performance of the resonator.

In one embodiment, after forming the cavity 40, the second trench 20 and the cavity 40 may be separated by the second electrode layer 120. The second trench 20 may also laterally reflect the acoustic wave, thereby improving the acoustic-electric conversion performance of the resonator accordingly.

Correspondingly, the present disclosure also provides a resonator. Referring to FIG. 13, FIG. 13 illustrates a structural schematic of the resonator according to the embodiment of the present disclosure.

The resonator may include a substrate; the adhesive layer 210 on the substrate; the piezoelectric stacked layer-structure 130 on the adhesive layer 210, where the piezoelectric stacked layer-structure 130 may include the working region 100s, the piezoelectric stacked layer-structure 130 at the working region 100s and the adhesive layer 210 may enclose the cavity 40, and the sidewall of the cavity 40 may expose the adhesive layer 210; and the release holes 30 passing through the piezoelectric stacked layer-structure 130, or the release holes 30 passing through the substrate, where the release holes 30 are connected to the cavity 40.

In one embodiment, the substrate may be the second substrate 200.

The resonator provided by various embodiments of the present disclosure may further include the adhesive layer 210 on the second substrate 200. The piezoelectric stacked layer-structure 130 may also on the adhesive layer 210; and the piezoelectric stacked layer-structure 130 at the working region 100s and the adhesive layer 210 may enclose the cavity 40, where the cavity 40 is not located in the second substrate 200. The formation of the cavity 40 may include steps of first forming the sacrificial layer and then removing the sacrificial layer through the release holes 30. The cavity 40 may be enclosed by the piezoelectric stacked layer-structure 130 and the adhesive layer 210. The piezoelectric stacked layer-structure 130 may be formed first; the sacrificial layer may be formed on the piezoelectric stacked layer-structure 130; next, the adhesive layer 210 may be attached to the sacrificial layer, and the release holes 30 may be formed, and then the sacrificial layer may be removed through the release holes 30; and the piezoelectric stacked layer-structure 130 may be directly formed on another substrate. As a result, a desirable interface and a flat surface may be provided for the formation of the piezoelectric stacked layer-structure 130, which is beneficial for improving the film quality of the piezoelectric stacked layer-structure 130, for example, the thickness uniformity, lattice orientation uniformity, film continuity and the like of each film layer in the piezoelectric stacked layer-structure 130, thereby improving the resonator performance.

The second substrate 200 may provide a process platform for subsequent processes. For example, the second substrate 200 may be used to provide a process platform for the formation of the adhesive layer 210 and the attaching between the adhesive layer 210 and the piezoelectric stacked layer-structure 130.

In one embodiment, the second substrate 200 may be any suitable substrate known to those skilled in the art. For example, the third substrate 200 may be made of a material including at least one of the materials mentioned below: silicon (Si), germanium (Ge), silicon germanium (SiGe), silicon carbon (SiC), silicon germanium (SiGeC), indium arsenide (InAs), Gallium arsenide (GaAs), indium phosphide (InP) or other III/V compound semiconductors; a multilayer-structure composed of such semiconductors; silicon-on-insulator (SOI), silicon-on-insulator (SSOI), silicon-germanium-on-insulator (S-SiGeOI), silicon germanium-on-insulator (SiGeOI), and germanium-on-insulator (GeOI); and a double side polished wafer (DSP), a ceramic substrate such as alumina, a quartz or glass substrate, and/or the combination thereof

During the formation of the cavity 40, the adhesive layer 210 may be used to seal the sacrificial layer, such that the cavity 40 may be formed after the sacrificial layer is removed using the release holes 30.

In one embodiment, the adhesive layer 210 may be a deformable material. For example, the adhesive layer 210 may be an organic material with strong adhesion, such that the attaching process may be achieved through the adhesive layer 210.

For example, the adhesive layer 210 may be a thermal-deformable material, and the thermal-deformable adhesive layer 210 may become soft after being heated, such that the adhesive layer 210 has strong plasticity. During the formation of the cavity 40, when the second back surface 210b of the adhesive layer 210 may be attached to the sacrificial layer 140 and the piezoelectric stacked layer-structure 130 exposed by the sacrificial layer 140, and the adhesive layer 210 may be squeezed/deformed and filled between the second substrate 200 and the piezoelectric stacked layer-structure 130. Therefore, the second substrate 200 may be attached to the first substrate 100 with the formed protrusion structure through the adhesive layer 210, thereby sealing the sacrificial layer 140 accordingly. Furthermore, the cavity 40 may be formed after the sacrificial layer is removed.

In one embodiment, the material of the adhesive layer 210 may be a dry film.

The dry film may be a viscous photoresist film used in semiconductor chip packaging or printed circuit board manufacturing. In one embodiment, the dry film photoresist may be manufactured by coating a solvent-free photoresist on a polyester base which is covered with a polyethylene film. When applying the dry film photoresist, the polyethylene film may be peeled off, the solvent-free photoresist may be pressed on a substrate, and a pattern may be formed in the dry film photoresist after exposure and development.

In other embodiments, the material of the adhesive layer may also be other organic material with strong adhesion, such as a die attach film (DAF).

In one embodiment, a portion of the adhesive layer 210 may be retained between the bottom of the cavity 40 and the second substrate 200, that is, the bottom of the cavity 40 may expose the adhesive layer 210, which is beneficial for ensuring that the adhesive layer 210 can seal the top and side walls of the sacrificial layer during the process of forming the cavity 40. For example, in one embodiment, the thickness of the adhesive layer 210 between the bottom of the cavity 40 and the second substrate 200 may be about 0.5 micrometer to about 35 micrometers, for example, 15 micrometers.

In other embodiments, according to the actual formation process of the cavity, the adhesion layer may not be retained between the bottom of the cavity and the second substrate, that is, the bottom of the cavity may expose the second substrate.

The piezoelectric stacked layer-structure 130 may be used to realize the mutual conversion between electrical signals and acoustic signals, such that the resonator may perform filtering processing on the signals.

In one embodiment, the piezoelectric stacked layer-structure 130 may include the working region 100s. The working region 100s may include a working region of the resonator for implementing the filtering function.

The piezoelectric stacked layer-structure 130 may include the second electrode layer 120, the piezoelectric layer 115 on the second electrode layer 120, and the first electrode layer 110 on the piezoelectric layer 115. The surface of the first electrode layer facing away from the second electrode layer is the first front surface, and the surface of the second electrode layer facing away from the first electrode layer is the first back surface. The cavity 40 may expose the first back surface of the second electrode layer 120.

In one embodiment, the second electrode layer 120 may be a top electrode.

The second electrode layer 120 may be made of a material including a conductive material or a semiconductor material. The conductive material may be a metal material with conductive properties including, for example, Al, Cu, Pt, Au, Ir, Os, Re, Pd, Rh, Ru, Mo, W, or a combination thereof. The semiconductor material may include, for example, Si, Ge, SiGe, SiC, SiGeC, or a combination thereof.

The piezoelectric layer 115 may be made of a piezoelectric material having piezoelectric effect. In other words, the piezoelectric material may be a crystalline material that generates voltage between two ends when it's subjected to pressure; and the piezoelectric effect of the piezoelectric material may be used to realize the mutual conversion between mechanical vibration (acoustic wave) and alternating current, thereby realizing the conversion of acoustic energy and electric energy.

The piezoelectric layer 115 may be a piezoelectric material having a wurtzite crystal structure, including ZnO, AlN, GaN, aluminum zirconate titanate, lead titanate, or a combination thereof. In one embodiment, the material of the piezoelectric layer 115 may be AlN.

In one embodiment, the first electrode layer 110 may be a bottom electrode.

The first electrode layer 110 may be made of a material including a conductive material or a semiconductor material. The conductive material may be a metal material with conductive properties including, for example, Al, Cu, Pt, Au, Ir, Os, Re, Pd, Rh, Ru, Mo, W, or a combination thereof. The semiconductor material may include, for example, Si, Ge, SiGe, SiC, SiGeC, or a combination thereof.

By setting the cavity 40, the piezoelectric stacked layer-structure 130 may be in contact with the air, such that the acoustic wave may be reflected at the interface between the cavity 40 and the piezoelectric stacked layer-structure 130 to generate normal vibrations when the resonator is operating, thereby making the resonator work normally. Moreover, the piezoelectric stacked layer-structure 130 may be in contact with air, which can effectively reflect the leakage acoustic wave of the resonator from the interface between the air and the piezoelectric stacked layer-structure 130 back to the surface of the substrate, thereby improving the conversion efficiency of electrical and mechanical energy, that is, improving the quality factor (Q factor).

In one embodiment, the cavity 40 may also expose a portion of the piezoelectric layer 115 at the working region 100s.

The resonator may further include the first trench 10 located in the piezoelectric stacked layer-structure 130. The opening of the first trench 10 may be connected to the cavity 40, and the bottom of the first trench 10 may expose the first electrode layer 110.

The opening of the first trench 10 may be connected to the cavity 40, such that the first trench 10 may laterally reflect the acoustic wave, thereby further reducing energy dissipation and improving the acoustic-electric conversion performance of the resonator. In other embodiments, the first trench may also be used to define the edge of the active region of the resonator, that is, the edge of the effective resonance region selected by the resonator; and the first trench and the second trench formed subsequently together may define the effective resonance region.

In one embodiment, the first trench 10 may pass through the piezoelectric layer 115, and the bottom of the first trench 10 may expose the first electrode layer 110.

The resonator may further include the second trench 20 located in the piezoelectric stacked layer-structure 130. The bottom of the second trench 20 may expose the second electrode layer 120; and the second trench 20 and the cavity 40 may be separated by the second electrode layer 120.

The second trench 20 and the cavity 40 may be separated by the second electrode layer 120. The second trench 20 may also laterally reflect the acoustic wave, thereby improving the acoustic-electric conversion performance of the resonator accordingly.

The release holes 30 may be connected the cavity 40. The release holes 30 may be used to release the sacrificial layer to form the cavity 40.

In one embodiment, the quantity of the release holes 30 may be more than one, thereby improving the subsequent removal efficiency of the sacrificial layer 140.

As an example, in one embodiment, the release hole 30 may pass through the piezoelectric stacked layer-structure 130.

In other embodiments, the release holes may also pass through the second substrate. Correspondingly, when the adhesive layer is retained between the top of the sacrificial layer and the second substrate, the release holes may correspondingly pass through the second substrate and the adhesive layer between the cavity top and the second substrate. The release holes pass through the second substrate, which is beneficial for preventing damage to the piezoelectric stacked layer-structure and further improving the resonator performance.

The resonator may be formed by the method for forming the resonator described in the above-mentioned embodiments or may be formed by other methods for forming the resonator. In one embodiment, specific description of the resonator may refer to the corresponding description in the above-mentioned embodiments, which may not be described in detail herein.

From the above-mentioned embodiments, it can be seen that the technical solutions provided by the present disclosure may achieve at least the following beneficial effects.

In the method for fabricating the resonator provided in various embodiments of the present disclosure, after forming the piezoelectric stacked layer-structure on the first substrate, the sacrificial layer covering the piezoelectric stacked layer-structure may be formed on the working region; then, the second back surface of the adhesive layer may be attached to the sacrificial layer and the piezoelectric stacked layer-structure exposed by the sacrificial layer, such that the adhesive layer covers the sidewalls of the sacrificial layer and is filled between the second substrate and the piezoelectric stacked layer-structure to achieve the attaching step; then, the first substrate may be removed, the release holes may be formed, and the sacrificial layer may be removed through the release holes to form the cavity. In various embodiments of the present disclosure, when the piezoelectric stacked layer-structure is formed, no sacrificial layer may be formed on the surface of the first substrate, and the surface of the first substrate has desirable flatness, which is beneficial for providing a desirable interface for forming the piezoelectric stacked layer-structure on the first substrate, thereby improving the formation quality of each film layer in the piezoelectric stacked layer-structure. For example, it is beneficial for improving the thickness uniformity, lattice orientation uniformity, film continuity and the like of each film layer in the piezoelectric stacked layer-structure and is further beneficial for improving the resonator performance accordingly. Moreover, in the present disclosure, the plasticity of the adhesive layer may also be utilized to attach the second substrate to the first substrate with the formed protrusion structure, and the sealing of the sacrificial layer may be implemented accordingly, such that it is beneficial for improving the convenience and operability of forming the cavity and saving cost.

The above-mentioned description is merely for the description of the preferred embodiments of the present disclosure, and it not intended to limit the scope of the present disclosure. Any changes and modifications based on the above-mentioned embodiments made by those skilled in the art are all within the scope of the present disclosure.

What is claimed is:

1. A method for fabricating a resonator, comprising:
providing a first substrate;
forming a piezoelectric stacked layer-structure on the first substrate, wherein the piezoelectric stacked layer-structure includes a working region, and a surface of the piezoelectric stacked layer-structure in contact with the first substrate is a first front surface;
forming a sacrificial layer covering the piezoelectric stacked layer-structure on the working region;
providing a second substrate;
forming an adhesive layer on the second substrate, wherein a surface of the adhesive layer in contact with the second substrate is a second front surface, and a surface of the adhesive layer opposite to the second front surface is a second back surface;
attaching the second back surface of the adhesive layer to the sacrificial layer and the piezoelectric stacked layer-structure exposed by the sacrificial layer, wherein the adhesive layer covers sidewalls of the sacrificial layer and is filled between the second substrate and the piezoelectric stacked layer-structure;
after attaching the second back surface of the adhesive layer to the sacrificial layer and the piezoelectric stacked layer-structure exposed by the sacrificial layer, removing the first substrate to expose the first front surface of the piezoelectric stacked layer-structure;
forming release holes passing through the piezoelectric stacked layer-structure, or forming release holes passing through the second substrate, wherein the release holes expose the sacrificial layer; and
removing the sacrificial layer through the release holes to form a cavity.

2. The method according to claim 1, wherein after forming the piezoelectric stacked layer-structure on the first substrate and before forming the sacrificial layer, the method further includes:
forming a first trench in the piezoelectric stacked layer-structure at the working region.

3. The method according to claim 2, wherein:
the piezoelectric stacked layer-structure includes a first electrode layer, a piezoelectric layer on the first electrode layer, and a second electrode layer on the piezoelectric layer; and a surface of the first electrode layer in contact with the first substrate is the first front surface;
when forming the first trench, a bottom of the first trench exposes the first electrode layer; and
after forming the cavity, an opening of the first trench is connected to the cavity.

4. The method according to claim 1, wherein after removing the first substrate to expose the first front surface of the piezoelectric stacked layer-structure, the method further includes:
forming a second trench in the piezoelectric stacked layer-structure at the working region.

5. The method according to claim 4, wherein:
the piezoelectric stacked layer-structure includes a first electrode layer, a piezoelectric layer on the first electrode layer, and a second electrode layer on the piezoelectric layer;
when forming the second trench, a bottom of the second trench exposes the second electrode layer; and
after forming the cavity, the second trench and the cavity are separated by the second electrode layer.

6. The method according to claim 1, wherein:
the adhesive layer is formed by a process including a spin coating process.

7. The method according to claim 1, wherein:
the adhesive layer is made of a material including a deformable material.

8. The method according to claim 1, wherein:
the adhesive layer is made of a material including a dry film and a die attach film.

9. The method according to claim 1, wherein attaching the second back surface of the adhesive layer to the sacrificial layer and the piezoelectric stacked layer-structure exposed by the sacrificial layer includes:
a bonding process, wherein a temperature of the bonding process is about 50° C. to about 300° C.

10. The method according to claim 1, wherein:
for forming the adhesive layer, a thickness of the adhesive layer is about 0.5 micrometer to about 40 micrometers.

11. The method according to claim 1, wherein:
when attaching the second back surface of the adhesive layer to the sacrificial layer and the piezoelectric stacked layer-structure exposed by the sacrificial layer, a portion of the adhesive layer is retained between a top surface of the sacrificial layer and the second substrate.

12. The method according to claim 11, wherein:
when attaching the second back surface of the adhesive layer to the sacrificial layer and the piezoelectric stacked layer-structure exposed by the sacrificial layer, a thickness of the adhesive layer between the top surface of the sacrificial layer and the second substrate is about 0.5 micrometer to about 35 micrometers.

13. The method according to claim 1, wherein removing the first substrate includes:
polishing the first substrate to remove a portion of the first substrate; and
after the first substrate is polished, removing a remaining portion of the first substrate using a wet etching process.

14. The method according to claim 1, wherein before forming the piezoelectric stacked layer-structure on the first substrate, the method further includes:
forming a buffer layer on the first substrate;
when removing the first substrate, using the buffer layer as a stop layer to remove the first substrate; and
after the first substrate is removed, removing the buffer layer.

15. The method according to claim 1, wherein forming the sacrificial layer includes:
forming a sacrificial material layer on the piezoelectric stacked layer-structure;
planarizing the sacrificial material layer;
after planarizing the sacrificial material layer, patterning the sacrificial material layer, wherein the sacrificial material layer at the working region is retained as the sacrificial layer.

16. A resonator, comprising:
a substrate;
an adhesive layer on the substrate;
a piezoelectric stacked layer-structure on the adhesive layer, wherein the piezoelectric stacked layer-structure includes a working region; the piezoelectric stacked layer-structure at the working region and the adhesive layer encloses a cavity; and a sidewall of the cavity exposes the adhesive layer; and
release holes passing through the piezoelectric stacked layer-structure, or passing through the substrate, wherein the release holes are connected to the cavity.

17. The resonator according to claim 16, wherein:
the adhesive layer is made of a material including one or more of a dry film, a die attach film, and a deformable material.

18. The resonator according to claim 16, wherein:
the piezoelectric stacked layer-structure includes a second electrode layer, a piezoelectric layer on the second electrode layer, and a first electrode layer on the piezoelectric layer;
a surface of the first electrode layer facing away from the second electrode layer is a first front surface, and a surface of the second electrode layer facing away from the first electrode layer is a first back surface; and
the cavity exposes the first back surface of the second electrode layer.

19. The resonator according to claim 18, further including:
a first trench in the piezoelectric stacked layer-structure, wherein an opening of the first trench is connected to the cavity, and a bottom of the first trench exposes the first electrode layer.

20. The resonator according to claim 18, further including:
a second trench in the piezoelectric stacked layer-structure, wherein a bottom of the second trench exposes the second electrode layer; and the second trench and the cavity are separated by the second electrode layer.
